(19) United States
(12) Patent Application Publication
(10) Pub. No.: US 2024/0304598 A1
(43) Pub. Date: Sep. 12, 2024

(54) MICROELECTRONIC DEVICES, AND RELATED MEMORY DEVICE PACKAGES AND ELECTRONIC SYSTEMS

(71) Applicant: Micron Technology, Inc., Boise, ID (US)

(72) Inventors: Chin Hui Chong, Singapore (SG); Seng Kim Dalson Ye, Singapore (SG); Hong Wan Ng, Singapore (SG); Kelvin Tan Aik Boo, Singapore (SG); Ling Pan, Singapore (SG); See Hiong Leow, Singapore (SG)

(21) Appl. No.: 18/424,693

(22) Filed: Jan. 26, 2024

Related U.S. Application Data
(60) Provisional application No. 63/489,047, filed on Mar. 8, 2023.

(51) Int. Cl. H01L 25/065; H10B 80/00

(52) U.S. Cl. CPC H01L 25/0657; H10B 80/00; H01L 2225/06506

(57) ABSTRACT

A microelectronic device includes a controller device, a first die vertically overlying the controller device, a second die vertically overlying the first die, and a wire. The first die includes a first pad horizontally separated from a horizontal center of the controller device by a first distance. The second die includes a second pad horizontally separated from the horizontal center of the controller device by a second distance larger than the first distance. The wire contacts the first pad of the first die and the second pad of the second die. Memory device packages and electronic systems are also disclosed.

### CROSS-REFERENCE TO RELATED APPLICATION

This application claims the benefit under 35 U.S.C. § 119(e) of U.S. Provisional Patent Application Ser. No. 63/489,047, filed Mar. 8, 2023, the disclosure of which is hereby incorporated herein in its entirety by this reference.

### TECHNICAL FIELD

The disclosure, in various embodiments, relates generally to the field of microelectronic device design. More specifically, the disclosure relates to microelectronic devices including wire-bonded memory dice that are stacked and configured in fan-in assemblies as memory device systems, and related to electronic systems containing stacked and fan-in assemblies of wire-bonded memory dice.

### BACKGROUND

Microelectronic devices often require complex external interconnections between memory devices and other devices such as processors, including logic and graphics processors. Memory devices that may be assembled by wire-bond technologies are generally provided as internal integrated circuits in computers or other electronic devices, and one type of memory devices includes, but is not limited to, volatile memory devices. One type of volatile memory device is a “not and” (NAND) logic based memory device. A NAND logic based memory device may include a 3-dimensional (3D) memory array including tiered strings of memory cells arranged in horizontal rows extending in a first horizontal direction and columns extending in a second horizontal direction, where the strings of memory cells are coupled to contact devices, such as in staircase contact structures. Another type of volatile memory device is a dynamic random-access memory (DRAM) device.

Wire-bonded memory devices may be assembled onto package boards or onto motherboards. Unfortunately, wire-bonding consumes available real estate on the package boards or motherboards.

### BRIEF DESCRIPTION OF THE DRAWINGS

FIG. 1 illustrates a simplified partial vertical cross-sectional view of a microelectronic device with a fan-in wire-bonded interposer flip-chip memory device controller configuration, according to some embodiments of the disclosure.

FIGS. 1A through IF illustrate simplified partial vertical cross-sectional (FIGS. 1A, 1B, 1C, 1E, and 1F) and simplified partial perspective (FIG. 1D) views at different processing stages of a method of forming the microelectronic device of FIG. 1, according to some embodiments of the disclosure.

FIG. 2 illustrates a simplified partial vertical cross-sectional view of a microelectronic device with a fan-in wire-bonded integrated redistribution layer, flip-chip memory device controller configuration, according to some embodiments of the disclosure.

FIG. 2A illustrates a simplified partial perspective view at a processing stage of a method of forming the microelectronic device of FIG. 2, according to some embodiments of the disclosure.

FIG. 3 illustrates simplified partial vertical cross-sectional view of a microelectronic device with a fan-in wire-bonded memory device controller and wire-bonded interposer configuration, according to some embodiments of the disclosure.

FIGS. 3A and 3B illustrate simplified partial perspective views at different processing stages of a method of forming the microelectronic device of FIG. 3, according to some embodiments of the disclosure.

FIGS. 4A and 4B illustrate simplified partial vertical cross-sectional (FIG. 4A) and simplified partial top-down (FIG. 4B) views of a microelectronic device with a fan-in wire-bonded interposer flip-chip memory device controller configuration, in an X-Y symmetry configuration including at least four memory die groups, according to some embodiments of the disclosure.

FIG. 5 illustrates a flow chart of a method of assembling a microelectronic device package, according to some embodiments of the disclosure.

FIG. 6 illustrates a flow chart of a method of manufacturing a microelectronic device package, according to additional embodiments of the disclosure.

FIG. 7 is a block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round or curved may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlxSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “integrated circuit” or “integrated-circuit device” may refer to a “microelectronic device” or a “nanoelectronic device,” each of which may be tied to a critical dimension exhibited by inspection. The term “integrated circuit” includes without limitation a memory device, as well as other devices (e.g., semiconductor devices) which may or may not incorporate memory. The term “integrated circuit” may include without limitation a logic device. The term “integrated circuit” may include without limitation a processor device such as a central-processing unit (CPU) or a graphics-processing unit (GPU). The term “integrated circuit” may include without limitation or a radiofrequency (RF) device. Further, an “integrated-circuit” device may incorporate memory in addition to other functions such as, for example, a so-called “system on a chip” (SoC) including a processor and memory, or an integrated-circuit device including logic and memory. Further, an “integrated-circuit” device may incorporate memory in addition to other functions such as, for example, a so-called “disaggregated device” where distinct integrated-circuit components are associated to produce the higher function such as that performed by an SoC, including a processor alone, a memory alone, a processor and a memory, or an integrated-circuit device including logic and memory.

As used herein, the term “substrate” means and includes a material (e.g., a base material) or construction upon which additional materials are formed. The substrate may be a semiconductor substrate. The substrate may be a base semiconductor material on a supporting structure, a metal electrode, or a semiconductor substrate having one or more materials, layers, structures, or regions formed thereon. The materials on the semiconductor substrate may include, but are not limited to, one or more of semiconductor materials, insulating materials, and conductive materials. The substrate may be a conventional silicon substrate or other bulk substrate comprising a layer of semiconductor material. As used herein, the term “bulk substrate” means and includes not only silicon wafers, but also silicon-on-insulator (“SOI”) substrates. The “bulk substrate” may be a SOI substrate such as a silicon-on-sapphire (“SOS”) substrate. The “bulk substrate” may be a SOI substrate such as a silicon-on-glass (“SOG”) substrate. The “bulk substrate” may include epitaxial layers of silicon on a base semiconductor foundation. The “bulk substrate” may include other semiconductor and/or optoelectronic materials. The semiconductor and/or optoelectronic materials may, for example, include one or more of silicon-germanium containing materials, germanium-containing materials, silicon-carbide containing materials, gallium arsenide-containing materials, gallium nitride-containing materials, and indium phosphide-containing materials. The substrate may be doped or undoped.

As used herein, the term “mounting substrate” means and includes structures that are configured to accept an integrated-circuit device. The mounting substrate may be a silicon bridge that is configured to connect more than on integrated-circuit device. The mounting substrate may be a package board that directly contacts an integrated circuit device such as a bare die containing a central-processing unit. The package board may be mounted on a printed wiring board (PWB). The mounting substrate may be a printed wiring board onto which at least one integrated circuit device and/or package board are mounted. The mounting substrate may include a disaggregated device. Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

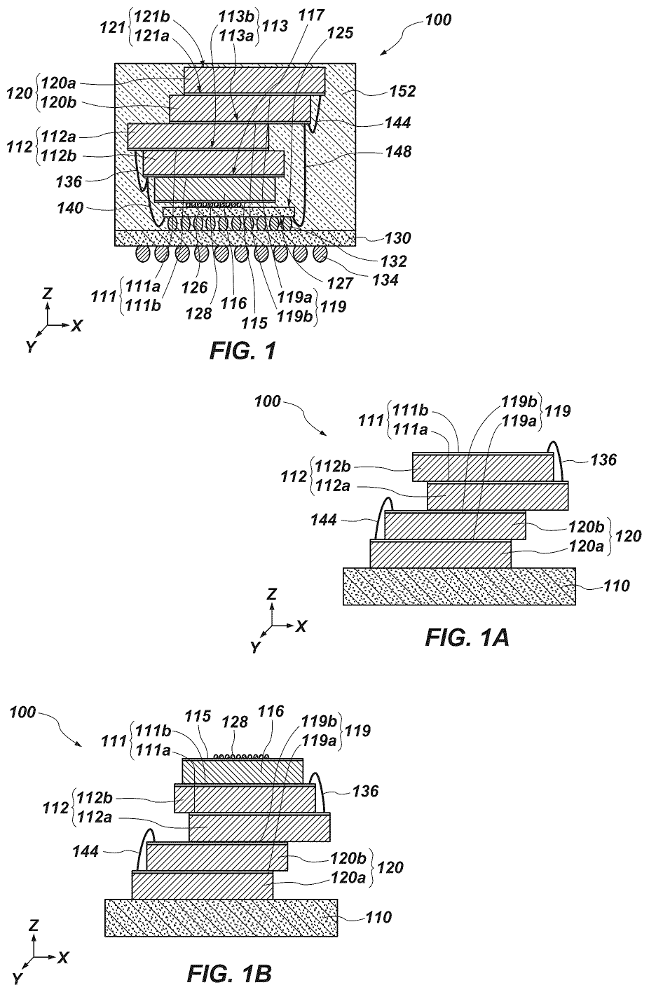

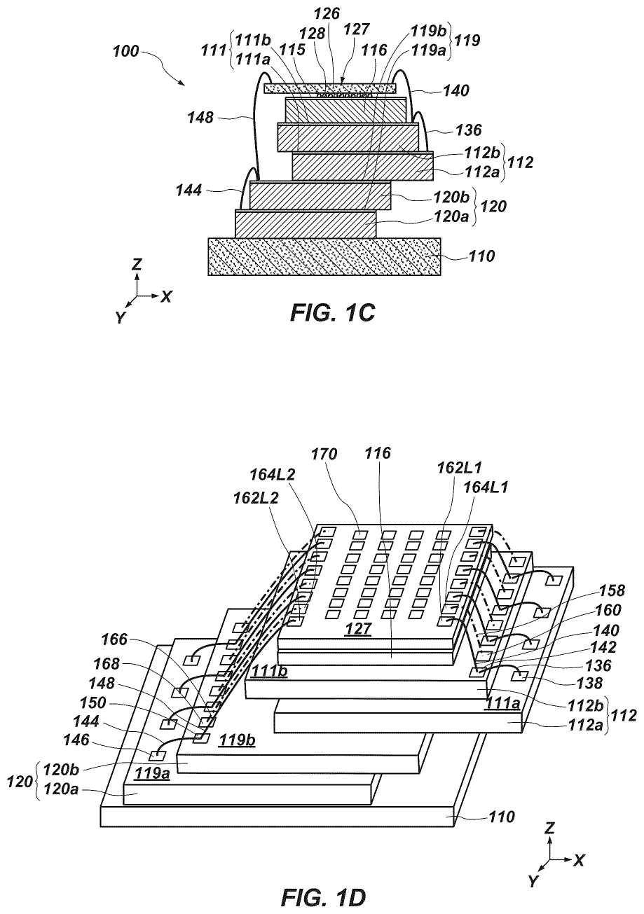

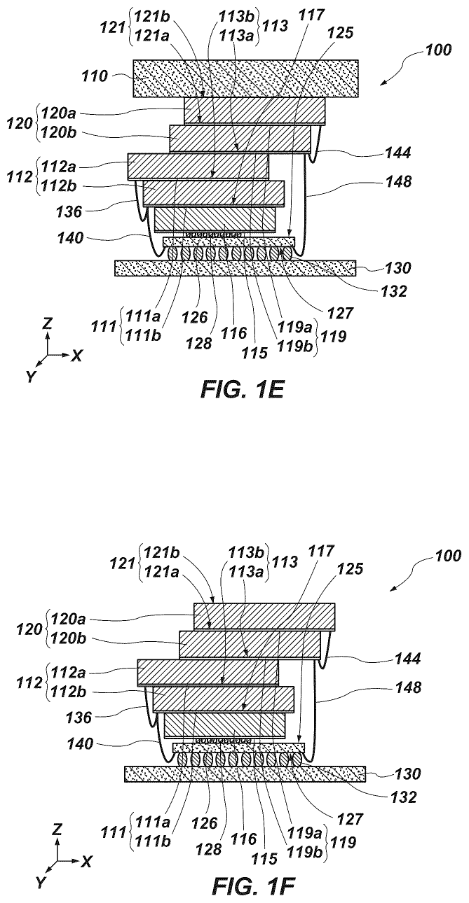

FIG. 1 illustrates a simplified partial vertical cross-sectional view of a microelectronic device 100, according to some embodiments of the disclosure. The microelectronic device 100 may be referred to as having a fan-in memory device assembly in a flip-chip configuration. The microelectronic device 100 may also be referred to herein as a flip-chip, fan-in memory device assembly 100, or a flip-chip, fan-in memory device assembly package 100.

As shown in FIG. 1, the flip-chip, fan-in memory device assembly 100 includes a first memory die group 112 and a second memory die group 120 that are vertically stacked (Z-direction), and adjacent one another. The first memory die group 112 may be referred to as a level-1 (L1) assembly 112, and the L1 assembly 112 is stacked with and adjacent a memory controller device 116. The second memory die group 120 may be referred to as a level-2 (L2) assembly 120, and the L2 assembly 120 is stacked with and adjacent the L1 assembly 112. As depicted in FIG. 1, the L2 assembly 120 is spaced apart from the memory controller device 116.

The L1 assembly 112 includes an L1 first die 112a and an L1 second die 112b that are vertically stacked (Z-direction), and adjacent one another. The L1 first die 112a includes an L1 first die metallization 111a and an L1 first die backside surface 113a that is opposite the L1 first die metallization 111a. The L1 second die 112b also includes an L1 second die metallization 111b, and an L1 second die backside surface 113b that is opposite the L1 second die metallization 111b. The memory controller device 116 includes a memory controller device metallization 115 and a memory controller device backside surface 117 that is opposite the memory controller device metallization 115. The L1 second die metallization 111b is physically coupled to the memory controller device 116 at the memory controller device backside surface 117, such that the L1 assembly 112 is assembled to the memory controller device 116, where the L1 assembly 112 is closer to the memory controller device 116 than is the L2 assembly 120. In some embodiments, the L1 second die metallization 111b is physically coupled to the memory controller device 116 at the memory controller device backside surface 117 by an adhesive material (not illustrated).

The L2 assembly 120 includes an L2 first die 120a and an L2 second die 120b that are vertically stacked (Z-direction), and adjacent one another. The L2 first die 120a includes an L2 first die metallization 119a and an L2 first die backside surface 121a that is opposite the L2 first die metallization 119a. The L2 second die 120b also includes an L2 second die metallization 119b, and an L2 second die backside surface 121b that is opposite the L2 second die metallization 119b. The L2 first die backside surface 121a and the L2 second die backside surface 121b are collectively shown as L2 die backside surfaces 121 in FIG. 1. In addition, the L2 first die metallization 119a and the L2 second die metallization 119b are collectively shown as L2 die metallizations 119 in FIG. 1. In some embodiments, the memory controller device 116 has control logic devices that prioritize storage locations, such as a given memory die that is closer to the memory controller device 116 may have a lower storage designation. Memory dice in the L1 assembly 112 may, for example, receive more memory storage and recall commands than memory dice in the L2 assembly 120. Put another way, the memory controller device 116 during operation, may send more storage and recall commands to the L1 first die 112a, than storage and recall commands sent to the L2 first die 120a. Other control logic circuitry may manage heat generation by temporarily sending more storage and recall commands to, e.g., the L2 second die 120b than to the L1 first die 112a, although the L1 first die 112a is physically closer to the memory controller device 116. In some embodiments, the memory controller device 116 has control logic circuitry configured such that storage and recall commands are prioritized by a relatively lower number of physical links between a given memory die and the memory controller device 116. Further illustration of the embodiment is discussed below with respect to FIG. 1D.

The memory controller device 116 is assembled to a redistribution device, such as an interposer device 126, proximate the memory controller device metallization 115, by an array of several memory controller electrical connections 128. The memory controller electrical connections 128 may include one or more of solder bumps, electrical pillars, electrical bumps, and interconnect pins that may be electrically inserted into the body of the interposer device 126. The interposer device 126 is assembled at a “device side” 125 or “assembly side” 125 to the memory controller device 116 by use of the memory controller electrical connections 128. The interposer device 126 is assembled to a printed wiring board substrate 130 at a “land side” 127 or a “board side” 127 with a land-side electrical contact array 132. When the printed wiring board substrate 130 is a package substrate 130, the land-side electrical contact array 132 is for further assembling to a board such as a motherboard by a motherboard electrical contact array 134. The printed wiring board substrate 130, when it is configured as a package substrate 130 as illustrated, may have the motherboard electrical contact array 134.

Electrical communication between the memory controller device 116 and each of the L1 assembly 112 and the L2 assembly 120 may be accomplished by a series of wire-bond interconnects that are coupled to the memory controller device 116 from the several metallizations within the L1 assembly 112 and the L2 assembly 120. For example with the L1 assembly 112, an L1 first-die originating wire-bond interconnect 136 extends from the L1 first die metallization 111a to the L1 second die metallization 111b; and an L1 first-die intervening wire-bond interconnect 140 continues electrical communication from the L1 first die 112a to the memory controller device 116 through the interposer device 126, where the L1 first-die intervening wire-bond interconnect 140 contacts the interposer device 126. An “originating wire-bond interconnect” means direct-contact interconnection between a given memory die is one of at least two wire-bond interconnections that interconnect the given memory die to a collective redistribution device such as in FIG. 1, the collective device is the interposer device 126. Put another way, interconnection between the L1 first die 112a and the memory controller device 116 includes the L1 first-die originating wire-bond interconnect 136 that makes direct contact with the L1 first die 112a, and the L1 first-die intervening wire-bond interconnect 140 completes interconnection between the L1 first die 112a and the interposer device 126. Interconnection of the L1 second die 112b to the memory controller device 116 is illustrated in FIG. 1D (described in further detail below).

With the L2 assembly 120 for the L2 first die 120a, an L2 first-die originating wire-bond interconnect 144 extends from the L2 first die metallization 119a to the L2 second die metallization 119b. Further, an L2 first-die intervening wire-bond interconnect 148 continues electrical communication from the L2 first die 120a to the memory controller device 116. Interconnection between the L2 first die 120a and the memory controller device 116 includes the L2 first-die originating wire-bond interconnect 144, the L2 first-die intervening wire-bond interconnect 148, and interconnection through the interposer device 126. Interconnection of the L2 second die 120b to the memory controller device 116 to is also illustrated in FIG. 1D.

An encapsulation mass 152 covers the interposer device 126, the memory controller device 116, and the L1 assembly 112 and the L2 assembly 120. The encapsulation mass 152 may extend to cover and protect electrical interconnections between the several devices. In some embodiments, the encapsulation mass 152 includes polysiloxane resin materials that are configured to be compatible to coefficients of thermal expansion of the silicon-based materials within the microelectronic devices of the L1 assembly 112 and the L2 assembly 120.

FIGS. 1A through IF illustrate simplified partial vertical cross-sectional (FIGS. 1A, 1B, 1C, 1E, and 1F) and simplified partial perspective (FIG. 1D) views at different processing stages of a method of forming the microelectronic device 100 of FIG. 1, in accordance with some embodiments of the disclosure. Referring to FIG. 1A, a carrier substrate 110 supports the L1 assembly 112 and the L2 assembly 120 during processing. The L1 assembly 112 has been provided (e.g., seated) above the L2 assembly 120. After the L2 assembly 120 is provided on the carrier substrate 110, the L1 assembly is provided on the L2 assembly.

Processing during the processing stage of FIG. 1A includes originating wire-bonding each of the L1 first die 112a and the L2 first die 120a. Following installation, the L1 first-die originating wire-bond interconnect 136 extends from the L1 first die metallization 111a to the L1 second die metallization 111b. Following installation, the L2 first-die originating wire-bond interconnect 144 extends from the L2 first die metallization 119a to the L2 second die metallization 119b.

Referring next to FIG. 1B, which illustrates the microelectronic device 100 at a processing stage following the processing stage described with reference to FIG. 1A, the memory controller device 116 may be provided (e.g., seated) on the L1 second die 112b above the L1 second die metallization 111b. In some embodiments, the memory controller device 116 is pre-processed to receive the electrical connections 128, where the electrical connections 128 may be placed upon an electrical bump bond-pad array (not illustrated).

Referring next to FIG. 1C, which illustrates the microelectronic device 100 at a processing stage following the process stage described with reference to FIG. 1B, the interposer device 126 may be provided (e.g., seated) on the several electrical connections 128 at the memory controller device metallization 115. The L1 first-die originating wire-bond interconnect 136 may be coupled to the memory controller device 116 by coupling the L1 first-die intervening wire-bond interconnect 140 on the interposer device 126 to a connection on the L1 second die metallization 111b. Similarly, the L2 first-die originating wire-bond interconnect 144 may be coupled to the memory controller device 116 by coupling the L2 first-die intervening wire-bond interconnect 148 on the interposer device 126 to a connection on the L2 second die metallization 119b.

Referring next to FIG. 1D, which illustrates the microelectronic device 100 at a processing stage following the process stage described with reference to FIG. 1C, the L1 first-die originating wire-bond interconnect 136 may be bonded to an originating bond pad 138 that is part of the L1 first die metallization 111a. The L1 first-die originating wire-bond interconnect 136 also contacts an intervening bond pad 142 that is a placeholder part of the L1 second die metallization 111b, for use by the L1 first die 112a. In some embodiments, the intervening bond pad 142 makes no electrical connection to circuitry within the L1 second die 112b, but the intervening bond pad 142 is a placeholder bond pad to facilitate continued interconnection of the L1 first die 112a to the interposer device 126. Electrical communication between the L1 first die 112a and the interposer device 126 is completed where the L1 first-die intervening wire-bond interconnect 140 contacts each of the intervening bond pad 142 and an L1 interposer first bond pad 162L1. Electrical communication of the L1 second die 112b to the memory controller device 116 includes an L1 second-die originating wire-bond interconnect 158 installed between an L1 second-die originating bond pad 160 and an L1 interposer subsequent bond pad 164L1. Consequently, the L1 first-die intervening wire-bond interconnect 140 and the L1 second-die single wire-bond interconnect 158 are laterally adjacent (Y-direction) one another. In some embodiments, the L1 second-die originating wire-bond interconnect 158 is as an L1 second-die “only” wire-bond interconnect 158 because it is the only wire-bond interconnection 158 originating from a given bond pad 160 for a given L1 second die 112b and terminating at the interposer device 126.

The L2 first-die originating wire-bond interconnect 144 may be bonded to an originating bond pad 146 that is part of the L2 first die metallization 119a. The L2 first-die originating wire-bond interconnect 144 may also contact an intervening bond pad 150 that is a placeholder part of the L2 second die metallization 119b, for use of the L2 first die 120a. Electrical communication between the L2 first die 120a and the interposer device 126 may be facilitated by way of contact between the L2 first-die intervening wire-bond interconnect 148 and an L2 interposer first bond pad 162L2. Electrical communication of the L2 second die 120b to the memory controller device 116 includes an L2 second-die originating wire-bond interconnect 166 provided between an L2 second-die originating bond pad 168 and an L2 interposer subsequent bond pad 164L2. The L2 first-die intervening wire-bond interconnect 148 and the L2 second-die originating wire-bond interconnect 166 are laterally adjacent (Y-direction) one another. Similar to the L1 second-die “only” wire-bond interconnect 158, in some embodiments, the L2 second-die originating wire-bond interconnect 166 is considered an L2 second-die “only” wire-bond interconnect 166. The package board 130 is coupled to the printed wiring board through the electrical contact array 132 (FIG. 1) by a series of originating wire-bond interconnects and intervening wire-bond interconnects at a wire-bond pad on a corresponding L1 second die 112b and L2 second die 120b.

Still referring to FIG. 1D, an interposer interconnect bond pad array 170 may be located on the interposer land side 127, in preparation to accept an interposer electrical contact array, such as the interposer electrical contact array 132 (FIG. 1).

In some embodiments, the memory controller device 116 includes control logic circuitry configured to permit storage and recall commands to be prioritized by a relatively lower number of physical links between a given memory die and the memory controller device 116. In an example embodiment, storage and recall commands may be prioritized by the most commands being sent to the L1 second die 112b because it is physically closest to the memory controller device 116. There may be a single wire-bond interconnect 158 between the L1 second die 112b and the interposer device 126. The second most commands may be sent to the L2 second die 120b because it is physically next closest to the memory controller device 116. There may be a single wire-bond interconnect 166 between the L2 second die 120b and the interposer device 126.

Referring next to FIG. 1E, which illustrates the microelectronic device 100 at a processing stage following the process stage described with reference to FIG. 1D, flip-chip, fan-in memory device assembly 100 the microelectronic device 100 formed through at the processing stages of FIGS. 1A through 1D may been inverted (Z-direction), and the interposer electrical contact array 132 may be coupled to the interposer interconnect bond pad array 170 (FIG. 1D) to facilitate a flip-chip, fan-in configuration of the microelectronic device 100. Processing may include thermal compression reflow of the interposer electrical contact array 132 onto the package board substrate 130.

Referring next to FIG. 1F, which illustrates the microelectronic device 100 (also referred to herein as the “flip-chip, fan-in memory device assembly 100”) at a processing stage following the process stage described with reference to FIG. 1E, the carrier substrate 110 (FIG. 1E) may be removed by a process, such as de-taping. In some embodiments, removal of the carrier substrate 110 is effectuated by activating a thermal-release adhesive material (not illustrated) that holds the L2 first die 120a to the carrier substrate 110. After removal of the carrier substrate 110, the flip-chip, fan-in memory device assembly 100 may be ready for receiving an encapsulation mass 152 (FIG. 1), such as a resin-based polymer overmolding material.

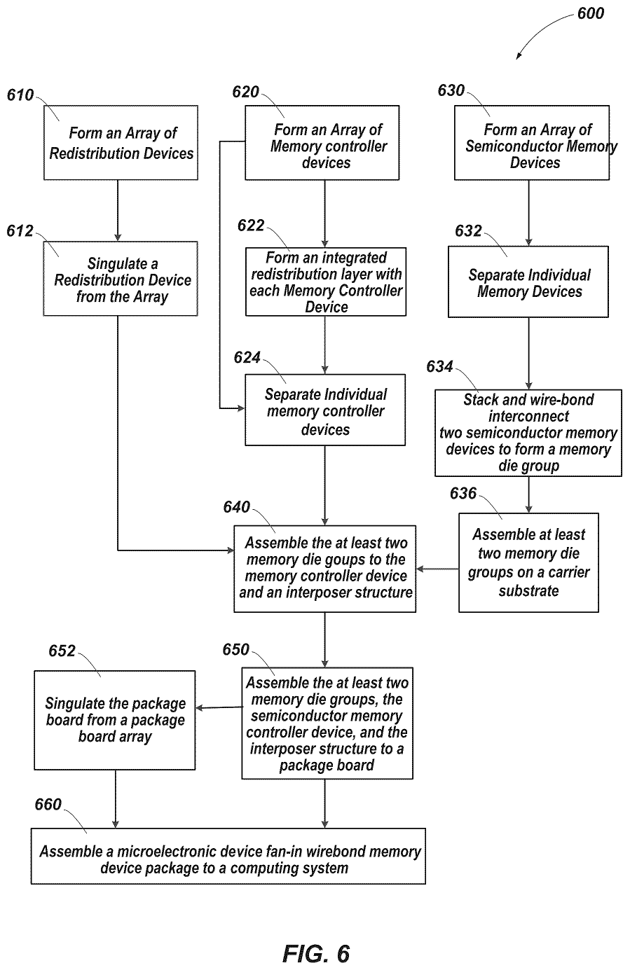

Referring again to FIG. 1, the flip-chip, fan-in memory device assembly 100 may be processed as one flip-chip, fan-in memory device assembly 100 among a wafer-level array of flip-chip, fan-in memory device assemblies, where the illustrated flip-chip, fan-in memory device assembly 100 has been singulated from the wafer-level array of flip-chip, fan-in memory device assemblies. In some embodiments, the flip-chip, fan-in memory device assembly 100 is singulated from a wafer-level array of four (4) flip-chip, fan-in memory device assemblies that are overmolded with the encapsulation mass 152. In some embodiments, the flip-chip, fan-in memory device assembly 100 may be singulated from a wafer-level array of eight (8) flip-chip, fan-in memory device assemblies. In some embodiments, the flip-chip, fan-in memory device assembly 100 may be singulated from a wafer-level array of sixteen (16) flip-chip, fan-in memory device assemblies. In some embodiments, the flip-chip, fan-in memory device assembly 100 is singulated from a wafer-level array of thirty-two (32) flip-chip, fan-in memory device assemblies. In some embodiments, the flip-chip, fan-in memory device assembly 100 is singulated from a wafer-level array of sixty-four (64) flip-chip, fan-in memory device assemblies. In some embodiments, the flip-chip, fan-in memory device assembly 100 is singulated from a wafer-level array of one hundred forty-four (144) flip-chip, fan-in memory device assemblies. Such processing may be further illustrated at 652 in FIG. 6.

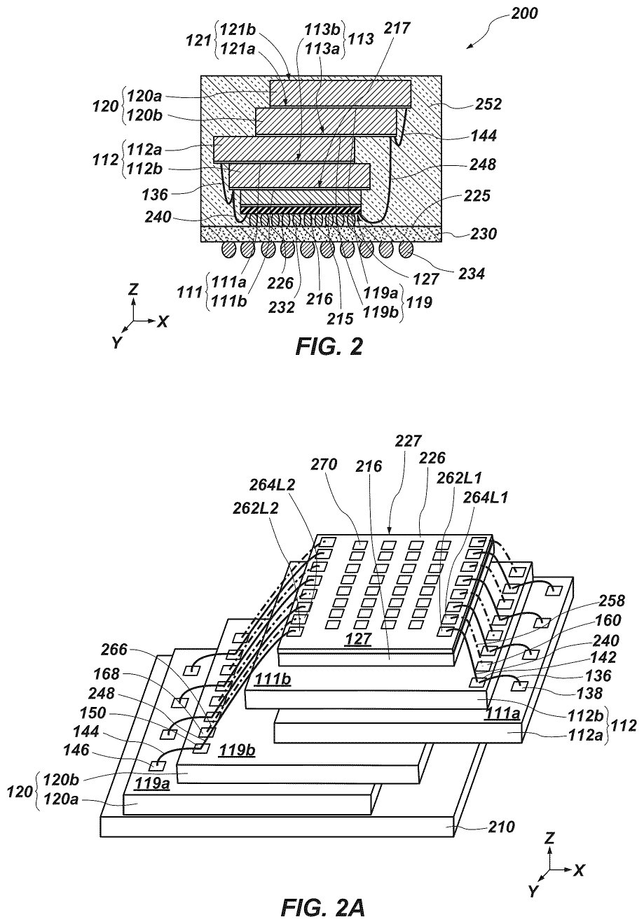

FIG. 2 illustrates a simplified partial vertical cross-sectional view of a microelectronic device 200, according to some embodiments of the disclosure. The microelectronic device 200 includes groups of memory dice in a wire-bonding fan-in stacked package. By contrast to the flip-chip, fan-in memory device assembly 100 illustrated in FIG. 1, the microelectronic device 200 includes a redistribution device having an integrated redistribution layer (iRDL) 226, and that is part of a memory controller device 216 (whereas the memory controller device 116 illustrated in FIG. 1 is electronically coupled to the interposer device 126). In some embodiments, the iRDL 226 is superposed on a memory controller device metallization 215 at a different processing act. In some embodiments, the iRDL 226 and the memory controller device metallization 215 are an integral unit. The memory controller device metallization 215 and the iRDL 226 may be assembled in a single processing act. The microelectronic device 200 may be referred to herein as a flip-chip iRDL memory device assembly 200, or a flip-chip iRDL memory device assembly package 200. Still referring to FIG. 2, similarly by contrast to the flip-chip memory device 100 illustrated in FIG. 1, wire-bonding interconnects are installed at the iRDL 226 compared to at the interposer device 126.

As shown in FIG. 2, wire-bonding interconnects may be installed at the iRDL 226. In addition, a first memory die group 112 and a second memory die group 120 are vertically stacked (Z-direction), and adjacent one another. The first memory die group 112 may be referred to as a level-1 (L1) assembly 112. The L1 assembly 112 may be stacked with and adjacent the memory controller device 216. The second memory die group 120 may be referred to as a level-2 (L2) assembly 120. The L2 assembly 120 may be stacked with and adjacent the L1 assembly 112.

The L1 assembly 112 includes an L1 first die 112a and an L1 second die 112b that are vertically stacked (Z-direction) and adjacent one another. The L1 first die 112a includes an L1 first die metallization 111a and an L1 first die backside surface 113a that is opposite the L1 first die metallization 111a. The L1 second die 112b also includes an L1 second die metallization 111b, and an L1 second die backside surface 113b that is opposite the L1 second die metallization 111b. The L1 first die backside surface 113a and the L1 second die backside surface 113b are collectively shown as L1 die backside surfaces 113 in FIG. 1. In addition, the L1 first die metallization 111a and the L1 second die metallization 111b are collectively shown as L1 die metallizations 111 in FIG. 1. The memory controller device 216 includes a memory controller device backside surface 217 that is opposite the memory controller device metallization 215. The L1 second die metallization 111b may be physically coupled to the memory controller device 216 at the memory controller device backside surface 217. The L1 assembly 112 may be assembled to the memory controller device 216 such that the L1 assembly 112 is relatively closer to the memory controller device 216 than is the L2 assembly 120.

The L2 assembly 120 includes an L2 first die 120a and an L2 second die 120b that are vertically stacked (Z-direction), and adjacent one another. The L2 first die 120a includes an L2 first die metallization 119a and an L2 first die backside surface 121a that is opposite the L2 first die metallization 119a. The L2 second die 120b also includes an L2 second die metallization 119b, and an L2 second die backside surface 121b that is opposite the L2 second die metallization 119b.

The memory controller device 216 is assembled to a package board 230 where the iRDL 226 contacts several memory controller electrical connections 232 in an array, such as solder bumps, electrical pillars, electrical bumps, and/or electrical pins, that may be inserted into the body of the package board 230. The memory controller electrical connections 232 are assembled at a “device side” 225 or “assembly side” 225 to the package board 230 by use of the memory controller electrical connections 232. The package board 230 may be assembled to a motherboard (not illustrated) with a land-side electrical contact array 234.

Electrical communication between the memory controller device 216 and each of the L1 assembly 112 and the L2 assembly 120, is accomplished by a series of wire-bond interconnects that are coupled to the memory controller device 216 from the several metallizations within the L1 assembly 112 and the L2 assembly 120. For example with the L1 assembly 112, an L1 first-die originating wire-bond interconnect 136, extends from the L1 first die metallization 111a, to the L1 second die metallization 111b, and an L1 first-die intervening wire-bond interconnect 240 continues electrical communication from the L1 first die 112a to the memory controller device 216, where the L1 first-die intervening wire-bond interconnect 240 contacts the memory controller device 216 at the iRDL 226. Put another way, interconnection between the L1 first die 112a and the memory controller device 216 includes the L1 first-die originating wire-bond interconnect 136, and the L1 first-die intervening wire-bond interconnect 240, and interconnection through the iRDL 226. Interconnection of the L1 second die 112b to the memory controller device 216 is illustrated at FIG. 2A.

With the L2 assembly 120 for the L2 first die 120a, an L2 first-die originating wire-bond interconnect 144, extends from the L2 first die metallization 119a, to the L2 second die metallization 119b. Further, an L2 first-die intervening wire-bond interconnect 248 continues electrical communication from L2 first die 120a to the memory controller device 216. Interconnection between the L2 first die 110a and the memory controller device 216 includes the L2 first-die originating wire-bond interconnect 144, and the L2 first-die intervening wire-bond interconnect 248, and interconnection through the iRDL 226. Interconnection of the L2 second die 120b to the memory controller device 216 to is also illustrated at FIG. 2A.

An encapsulation mass 252 covers the iRDL 226, the memory controller device 216, the L1 assembly 112, and the L2 assembly 120. The encapsulation mass 252 may extend to cover and protect electrical interconnections between the several devices.

FIG. 2A illustrates a simplified partial perspective view at a processing stage of a method of forming the microelectronic device 200 of FIG. 2, according to some embodiments of the disclosure. The processing stage of FIG. 2A may follow processing similar to that previously described with reference to FIG. 1B, whereas in FIG. 2A, the iRDL 226 is present in lieu of the redistribution device 126 in FIG. 1B. The microelectronic device 200 is provided (e.g., seated) on a carrier substrate 210. The L1 first-die originating wire-bond interconnect 136 may be bonded to an originating bond pad 138 that is part of the L1 first die metallization 111a, and the L1 first-die originating wire-bond interconnect 136 also contacts an intervening bond pad 142 that is a placeholder part of the L1 second die metallization 111b. Electrical communication between the L1 first die 112a and the iRDL 226 may be facilitated by way of contact between L1 first-die intervening wire-bond interconnect 240 and a L1 iRDL first bond pad 262L1. Electrical communication of the L1 second die 112b to the memory controller device 216 includes an L1 second-die originating wire-bond interconnect 258 provided between an L1 second-die originating bond pad 160 and an L1 iRDL subsequent bond pad 264L1. The L1 first-die intervening wire-bond interconnect 240 and the L1 second-die originating wire-bond interconnect 158 are laterally adjacent (Y-direction) one another. Similar to the L1 second-die “only” wire-bond interconnect 158 described with reference to FIG. 1D, in some embodiments, the L1 second-die originating wire-bond interconnect 258 is considered an L1 second-die “only” wire-bond interconnect 258.

The L2 first-die originating wire-bond interconnect 144 may be bonded to an originating bond pad 146 that is part of the L2 first die metallization 119a. The L2 first-die originating wire-bond interconnect 144 may contact a placeholder intervening bond pad 150 that is part of the L2 second die metallization 119b. Electrical communication between the L2 first die 120a and the iRDL 226 may be facilitated by way of contact between the L2 first-die intervening wire-bond interconnect 248 and an L2 iRDL first bond pad 262L2. Electrical communication of the L2 second die 120b to the memory controller device 216 includes an L2 second-die originating wire-bond interconnect 266 provided between an L2 second-die originating bond pad 168 and an L2 iRDL subsequent pond pad 264L2. The L2 first-die intervening wire-bond interconnect 248 and the L2 second-die originating wire-bond interconnect 266 may be laterally adjacent (Y-direction) one another.

An iRDL interconnect bond pad array 270 may be located on the iRDL land side 227, in preparation to accept the memory controller electrical connections 232, which double as the interposer electrical contact array 232 (FIG. 2) because of the iRDL 226.

Referring again to FIG. 2, the iRDL flip-chip, fan-in memory device assembly 200 may be processed as one iRDL flip-chip, fan-in memory device assembly 200 among a wafer-level array of iRDL flip-chip, fan-in memory device assemblies, where the illustrated flip-chip, fan-in memory device assembly 200 has been singulated from the wafer-level array of flip-chip, fan-in memory device assemblies. The number of iRDL flip-chip, fan-in memory array devices may be singulated from the wafer-level array in number embodiments, similarly to those enumerated for the memory device assembly 100 illustrated and described for FIG. 1.

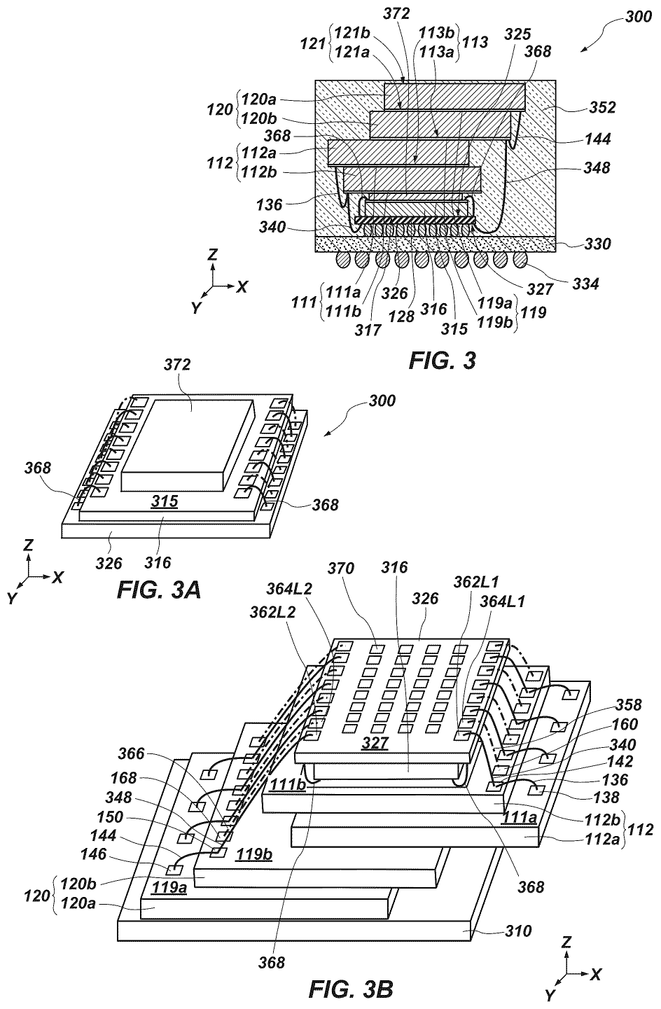

FIG. 3 illustrates a simplified partial vertical cross-sectional view of a microelectronic device 300, according to some embodiments of the disclosure. The microelectronic device 300 includes groups of memory dice in a wire-bonding fan-in stacked. By contrast to the flip-chip, fan-in memory device assembly 100 illustrated in FIG. 1, the microelectronic device 300 includes wire-bonding interconnects to a memory controller device 316 (whereas the memory controller device 116 illustrated in FIG. 1 is electronically coupled to the interposer device 126 by the electrical contact array 132). The microelectronic device 300 may be referred to herein as a flip-chip, wire-bonded controller microelectronic device assembly 300, or a flip-chip, wire-bonded controller microelectronic device assembly package 300.

The flip-chip, fan-in wire-bonded controller memory device assembly 300 includes a first memory die group 112 and a second memory die group 120 that are vertically stacked (Z-direction), and adjacent one another. The first memory die group 112 may be referred to as a level-1 (L1) assembly 112, and the L1 assembly 112 is stacked with and adjacent a memory controller device 316. The second memory die group 120 may be referred to as a level-2 (L2) assembly 120, and the L2 assembly 120 is stacked with and adjacent the L1 assembly 112.

Still referring to FIG. 3, the L1 assembly 112 includes an L1 first die 112a and an L1 second die 112b that are vertically stacked (Z-direction), and adjacent one another. The L1 first die 112a includes an L1 first die metallization 111a and an L1 first die backside surface 113a that is opposite the L1 first die metallization 111a. The L1 second die 112b also includes an L1 second die metallization 111b, and an L1 second die backside surface 113b that is opposite the L1 second die metallization 111b. The memory controller device 316 includes a memory controller device metallization 315 and a memory controller device backside surface 317 that is opposite the memory controller device metallization 315. The L1 second die metallization 111b is physically coupled to a spacer structure 372, which provides clearance space (“head room”) for interposer-to-memory controller device wire-bond interconnects 368. Consequently, the L1 second die metallization 111b and the memory controller device metallization 315 are face-to-face, and spaced apart by the spacer structure 372. The L1 assembly 112 is assembled to the memory controller device 316, where the L1 assembly 112 is closer to the memory controller device 316 than is the L2 assembly 120.

The L2 assembly 120 includes an L2 first die 120a and an L2 second die 120b that are vertically stacked (Z-direction), and adjacent one another. The L2 first die 120a includes an L2 first die metallization 119a, and an L2 first die backside surface 121a that is opposite the L2 first die metallization 119a. The L2 second die 120b also includes an L2 second die metallization 119b, and an L2 second die backside surface 121b that is opposite the L2 second die metallization 119b.

The memory controller device 316 is assembled against a redistribution device, such as an interposer device 326, at a side opposite the memory controller device metallization 315. The interposer device 326 may be assembled at a “device side” 325 or “assembly side” 325 to the memory controller device 316 by use of adhesive material. The interposer device 326 is assembled to a printed wiring board substrate 330 at a “land side” 327 or a “board side” 327 with a land-side electrical contact array 332. When the printed wiring board substrate 330 is a package substrate 330, the land-side electrical contact array 332 is for further assembling to a board such as a motherboard by a motherboard electrical contact array 334. The printed wiring board substrate 330, when it is configured as a package substrate 330 as illustrated, may have the motherboard electrical contact array 334.

In some embodiments, the several devices and structures up to the land-side electrical contact array 332, but not including the package board 330, are assembled to a motherboard located at the placeholder site illustrated by the package board 330. For example, after forming an encapsulation mass in contact with a carrier substrate (e.g., carrier substrate 310 in FIG. 3B), a pre-placed array of the electrical contact array 332, may be uncoverable by abrading some of the encapsulation mass, singulating a given assembly and mounting onto a motherboard.

Electrical communication between the memory controller device 316 and each of the L1 assembly 112 and the L2 assembly 120 may be accomplished by a series of wire-bond interconnects that are coupled to the memory controller device 316 from the several metallizations within the L1 assembly 112 and the L2 assembly 120. For example with the L1 assembly 112, an L1 first-die originating wire-bond interconnect 136, extends from the L1 first die metallization 111a to the L1 second die metallization 111b; and an L1 first-die intervening wire-bond interconnect 340 continues electrical communication from the L1 first die 112a to the memory controller device 316, where the L1 first-die intervening wire-bond interconnect 340 contacts the interposer device 326 in a manner similarly as the L1 first-die intervening wire-bond interconnect 140 (FIG. 1) continues electrical communication from the L1 first die 112a to the memory controller device 116. Put another way, interconnection between the L1 first die 112a and the memory controller device 316 includes the L1 first-die originating wire-bond interconnect 136, and the L1 first-die intervening wire-bond interconnect 340, interconnection through the interposer device 326, and interconnection from the interposer device 326 to the memory controller device 316 by the interposer-to-memory controller device wire-bond interconnects 368. Interconnection of the L1 second die 112b to the memory controller device 116 is illustrated at FIG. 3B.

With the L2 assembly 120 for the L2 first die 120a, an L2 first-die originating wire-bond interconnect 144 extends from the L2 first die metallization 119a, to the L2 second die metallization 119b. Further, an L2 first-die intervening wire-bond interconnect 348 continues electrical communication from the L2 first die 120a to the memory controller device 316. Interconnection between the L2 first die 210a and the memory controller device 316 includes the L2 first-die originating wire-bond interconnect 144, the L2 first-die intervening wire-bond interconnect 348, and interconnection through the interposer device 326. Interconnection of the L2 second die 120b to the memory controller device 316 to is also illustrated in FIG. 3B.

An encapsulation mass 352 covers the interposer device 326, the memory controller device 316, and the L1 assembly 112 and the L2 assembly 120. The encapsulation mass 352 may extend to cover and protect electrical interconnections between the several devices.

FIGS. 3A and 3B illustrate simplified partial perspective views at different processing stages of a method of forming the microelectronic device 300 of FIG. 3, according to some embodiments of the disclosure. Referring to FIG. 3A, the interposer-to-memory controller device wire-bond interconnects 368 have been installed to interconnect the memory controller device 316 to the interposer device 326. Further, the spacer structure 372 has been physically installed above (Z-direction) the memory controller device metallization 315.

Referring next to FIG. 3B, which illustrates the microelectronic device 300 at a processing stage following the processing stage described with reference to FIG. 3A, the sub-assembly including the memory controller device 316, the interposer device 326, and the spacer structure 372 has been inverted and assembled to the L1 assembly 112 (which was previously assembled to the L2 assembly 120). Additionally, more wire-bond interconnects are illustrated, along with the wire-bond interconnects illustrated in FIGS. 3 and 3A. The L1 first-die originating wire-bond interconnect 136 may be bonded to an originating bond pad 138 that is part of the L1 first die metallization 111a, and the L1 first-die originating wire-bond interconnect 136 may contact an intervening bond pad 142. The intervening bond pad 142 may be a placeholder part of the L1 second die metallization 111b. Electrical communication between the L1 first die 112a and the interposer device 326 may be facilitated by way of contact between the L1 first-die intervening wire-bond interconnect 340 and an L1 interposer first bond pad 362L1. Electrical communication of the L1 second die 112b to the memory controller device 316 includes an L1 second-die originating wire-bond interconnect 358 provided installed between an L1 second-die originating bond pad 160 and an L1 interposer subsequent bond pad 364L1. The L1 first-die intervening wire-bond interconnect 140 and the L1 second-die originating wire-bond interconnect 358 are laterally adjacent (Y-direction) one another.

The L2 first-die originating wire-bond interconnect 144 may be bonded to an originating bond pad 146 that is part of the L2 first die metallization 119a; and the L2 first-die intervening wire-bond interconnect 348 may contact an intervening bond pad 150 that is part of the L2 second die metallization 119b. Electrical communication between the L2 first die 120a and the interposer device 326 may be facilitated by way of contact between the L2 first-die intervening wire-bond interconnect 348 and an L2 interposer first bond pad 362L2. Electrical communication of the L2 second die 120b to the memory controller device 116 includes an L2 second-die originating wire-bond interconnect 366 provided between an L2 second-die originating bond pad 168 and an L2 interposer subsequent bond pad 364L2. The L2 first-die intervening wire-bond interconnect 348 and the L2 second-die originating wire-bond interconnect 366 may be laterally adjacent (Y-direction) one another. Similar to the L2 second-die “only” wire-bond interconnect 166 previously described with reference to FIG. 1D, in some embodiment, the L2 second-die originating wire-bond interconnect 366 is considered an L2 second-die “only” wire-bond interconnect 366.

An interposer interconnect bond pad array 370 may be located on the interposer land side 327, in preparation to accept the interposer electrical contact array 332 (FIG. 3). The interposer-to-memory controller device wire-bond interconnects 368 may have sufficient clearance in the Z-direction after placement of the spacer structure 372 (FIGS. 3 and 3A) to provide head space for the interposer-to-memory controller device wire-bond interconnects 368 above the L1 second die 112b.

Referring again to FIG. 3, the flip-chip, wire-bonded controller microelectronic device assembly 300 may be processed as one flip-chip, wire-bonded controller microelectronic device assembly 300 among a wafer-level array of flip-chip, wire-bonded controller microelectronic device assemblies. The flip-chip, wire-bonded controller microelectronic device assembly 300 may be singulated from the wafer-level array of flip-chip, fan-in memory device assemblies.

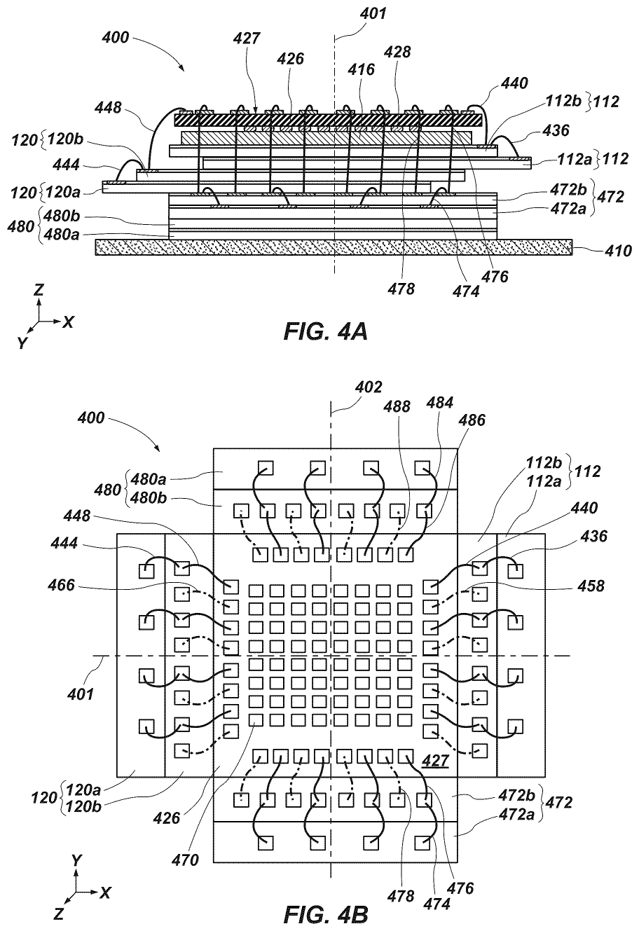

FIGS. 4A and 4B illustrate simplified partial vertical cross-sectional (FIG. 4A) and simplified partial top-down (FIG. 4B) views of a microelectronic device 400, according to some embodiments of the disclosure. The microelectronic device 400 is provided (e.g., seated) on a carrier substrate 410. The microelectronic device 400 may have a fan-in wire-bonded interposer flip-chip memory device controller configuration, in an X-Y symmetry configuration including at least four memory die groups 112, 120, 472 and 480 similar to the microelectronic device 100 illustrated in FIG. 1, and processing acts previously described with reference to FIGS. 1A through IF, the microelectronic device 400 may be have a wire-bonding fan-in stacked package configuration. The configuration may include two memory die groups 112 and 120 oriented about an X-direction bilateral symmetry line 401, and two memory die groups 472 and 480 oriented about a Y-direction bilateral symmetry line 402.

Collectively referring to FIGS. 4A and 4B, the first memory die group 112 may be located closest to a memory controller device 416. The memory controller device 416 may be coupled to a redistribution device 426, such as an RDL device 426, through an array of several memory controller electrical connections 428. The first memory die group 112 may be referred to as a level-1 (L1) assembly 112, and the second memory die group 120 may be referred to as an L2 assembly 120. The L2 assembly 120 may be stacked with and adjacent to the L1 assembly 112. The L2 assembly 120 may be spaced apart from the memory controller device 416. The third memory die group 472 may be referred to as an L3 assembly 472, and the fourth memory die group 480 may be referred to as an LA assembly 480. The L3 assembly 472 may be stacked with and adjacent to the L4 assembly 480. In some embodiments, the L4 assembly 480 is farthest from the memory controller device 416, compared to each of the L1 assembly 112, the L2 assembly 120, and the L3 assembly 472. “X-Y symmetry” may mean, e.g., the L1 assembly 112 and the L2 assembly 120 are arranged about a symmetry line 401, and the L3 assembly 472 and the LA assembly 480 are arranged about a symmetry line 402 that is orthogonal to the other symmetry line 401.

Wire-bonding is illustrated similar to that illustrated in FIGS. 1 and 1D. A first-die originating wire-bond interconnect 436 extends from the L1 first die 112a to the L1 second die 112b; and an L1 first-die intervening wire-bond interconnect 440 continues electrical communication from the L1 first die 112a to the memory controller device 416 through the interposer device 426 at a land side 427 thereof. The L1 first-die intervening wire-bond interconnect 440 contacts the interposer device 426. Electrical communication of the L1 second die 112b to the memory controller device 416 includes an L1 second-die originating wire-bond interconnect 458 provided installed between an L1 second-die originating bond pad and an L1 interposer subsequent bond pad. In addition, electrical communication of the L2 second die 120b to the memory controller device 116 includes an L2 second-die originating wire-bond interconnect 466 provided between an L2 second-die originating bond pad and an L2 interposer subsequent bond pad. An L2 first-die originating wire-bond interconnect 444 extends from the L2 first die 420a to the L2 second die 420b. Further, an L2 first-die intervening wire-bond interconnect 448 continues electrical communication from L2 first die 120a to the memory controller device 416 through the interposer device 426. Interconnection of the L2 second die 120b with the memory controller device 416 is illustrated in FIG. 4B.

Wire-bond interconnections may be provided from the L3 assembly 472 to the interposer device 426 by way of an L3 first-die originating wire-bond interconnect 474. The L3 first-die originating wire-bond interconnect 474 directly contacts the L3 first die 472a and the L3 second die 472b. An L3 first-die intervening wire-bond interconnect 476 may complete interconnection between the L3 first die 472a and the interposer device 426. Electrical communication of the L3 second die 472b to the memory controller device 416 includes an L3 second-die originating wire-bond interconnect 478 provided between the L3 second die 472b and the memory controller device 416, through the interposer device 426. The L3 first-die intervening wire-bond interconnect 476 and the L3 second-die originating wire-bond interconnect 478 are laterally adjacent (X-direction) one another.

Referring to FIG. 4B, wire-bond interconnections from the L4 assembly 480 to the memory controller device 416 may be provided by way of an L4 first-die originating wire-bond interconnect 484 that makes direct contact with the L4 first die 480a and the LA second die 480b. An L4 first-die intervening wire-bond interconnect 486 may complete interconnection between the L4 first die 480a and the interposer device 426. Electrical communication between the L4 second die 480b and the memory controller device 416 may be facilitated by an L4 second-die originating wire-bond interconnect 488 provided between the L4 second-die 480b and the memory controller device 416, through the interposer device 426. The L4 first-die intervening wire-bond interconnect 486 and the L4 second-die originating wire-bond interconnect 488 may be laterally adjacent (X-direction) one another.

The land side 427 of the interposer device 426 may have an interposer interconnect bond pad array 470 for interconnection with land side electrical bumps (e.g., electrical bumps 132, FIG. 1; electrical bumps 232, FIG. 2; and electrical bumps 332, FIG. 3). The bond pad array 470 may have several occurrences greater than sixty-four (64), as illustrated.

In some embodiments, the flip-chip, fan-in memory device assembly 100 (FIG. 1) is combined with L3 and L4 assemblies, similar to the microelectronic device 400 illustrated in FIGS. 4A and 4B. In some embodiments, the iRDL flip-chip, fan-in memory device assembly 200 (FIG. 2) is combined with L3 and L4 assemblies, similar to the microelectronic device 400 illustrated in FIGS. 4A and 4B. In some embodiments the wire-bonded memory device controller fan-in microelectronic device assembly 300 (FIG. 3) is combined with L3 and LA assemblies, similar to the microelectronic device 400 illustrated in FIGS. 4A and 4B. If L3 assemblies and L4 assemblies are combined, control logic circuitry within the memory controller device, e.g., the memory controller device 416, may be similar to disclosed functions such as heat management, memory die usage management depending upon memory die proximity to the memory controller device, and other functions useful to operating a disclosed memory device.

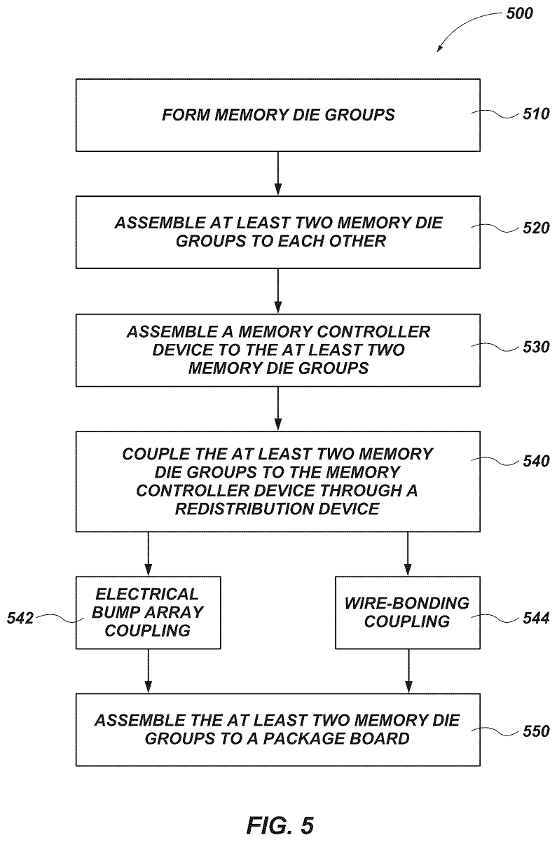

FIG. 5 illustrates a flow chart of a method 500 of assembling a microelectronic device package of the disclosure (e.g., the microelectronic device packages 100, 200, 300 and 400 described above), in accordance with some embodiments of the disclosure. For the purpose of the method of assembling 500, the processes of manufacturing the individual parts, such as the semiconductor dies, microelectronic devices, interposers, and so on, are not described in detail herein. The manufacturing processes are described in greater detail below with respect to FIG. 6.

At act 510, the method 500 incudes forming memory die groups, such as the first memory die group 112 (the L1 assembly 112, which includes the L1 first die 112a and the L1 second die 112b). Forming the memory die group may also include forming a first-die originating wire-bond interconnect, such at the L1 group first-die originating wire-bond interconnect 136 (FIG. 1) that extends from the L1 first die 112a to the L1 second die 112b.

At act 520, the method 500 includes assembling at least two memory die groups to each other. In a non-limiting example embodiment, the L1 assembly 112 and the L2 assembly 120 (FIG. 1A) are assembled to a carrier substrate 110.

At act 530, the method 500 includes assembling a memory controller device to at least an L1 assembly and an L2 assembly. In a non-limiting example embodiment, the memory controller device 116 (FIG. 1B) is assembled to the L1 assembly 112 and the L2 assembly 120.

At act 540, the method 500 includes coupling the at least two memory die groups to the memory controller device through a redistribution device, such as the interposer device 126 (FIG. 1) or the iRDL 226 (FIG. 2). In a non-limiting example embodiment, the L1 assembly 112 and the L2 assembly 120 are coupled to the memory controller device 216 (FIG. 2) through the iRDL 226, by a processing act similar to that accomplished and illustrated at FIGS. 1C and 1D. Coupling acts include installing the intervening wire-bond interconnects 240 and 248 (FIGS. 2 and 2A) at a processing act similar to that illustrated at FIGS. 1C and 1D.

At act 542, coupling is done through an electrical bump array such as through the electrical connections 128 (FIG. 1). Also at act 542, coupling is completed through the iRDL 226 and with intervening and originating wire-bonds 240 and 258, respectively, and with intervening and originating wire-bonds 248 and 266, respectively (FIG. 2A).

At act 544, coupling is done by first wire-bonding a memory controller device to a redistribution device, followed by wire-bonding the redistribution device to the at least two memory die groups. In a non-limiting example embodiment, interconnection from the interposer device 326 to the memory controller device 316 (FIG. 3A) is accomplished by the interposer-to-memory controller device wire-bond interconnects 368, followed by assembling the memory controller device 316 and the redistribution device 326 to the L1 assembly 112 (FIG. 3B) and completing wire-bonding with the intervening and originating wire-bond interconnects 340 and 358, respectively, and with the intervening and originating wire-bond interconnects 348 and 366, respectively (FIG. 3B).

At act 550, the method 500 includes assembling the at least two memory die groups to a package board. In a non-limiting example embodiment, the L1 assembly 112, the L2 assembly 120, the memory controller device 116 and the interposer device 126 (FIG. 1) are assembled on the package board 130, such as by reflow of the electrical connections 128 (FIG. 1). The electrical connections 128 may be reflowed onto individual bond pads of the interposer interconnect bond pad array 170 (FIG. 1).

FIG. 6 illustrates a flow chart re of a method 600 of manufacturing a microelectronic device package of the disclosure (e.g., any of the microelectronic device packages 100, 200, 300, and 400 described above), in accordance with embodiments of the disclosure. One or more (e.g., each) of the components of the resulting microelectronic device package may be formed individually, and then assembled to form the microelectronic device package. Therefore, the different forming processes may operate in parallel and/or do not have any specific order in which they are completed. Once the individual components are formed they may be assembled through the process described above in FIG. 5.

For the memory devices, as well as the memory controller devices, each of the components may be formed in arrays formed on a substrate, such as a semiconductor wafer through build up processes, such as deposition, sputtering, etc., material removal processes, such as etching (e.g., wet etch, dry etch, etc.), lithography (e.g., photolithography, optical lithography, UV lithography, etc.), etc., and filling processes. Once the array of components is formed the array may be separated into individual components through a separation process, such as a dicing process. For the redistribution devices, an array of interposers may be assembled at a wafer level. For the integrated redistribution layer devices, the memory controller devices may be manufactured in a single processing setting that includes the iRDL assembly above metallization or integrated with metallization. Alternatively, the iRDL may be manufactured during a subsequent processing setting.

An array of interposer devices may be formed at act 610, such as using wafer-level assembly acts. Individual interposer devices may be singulated from the array of interposer devices at 612, such as by sawing, scoring and cracking, and combinations thereof.

An array of memory controller devices may be formed at act 620, such as by semiconductor device processing at the wafer level. Alternatively to processing at act 610 and act 612, integrated redistribution layer devices may be formed during forming the array of memory controller devices at the wafer level at act 622. Individual memory controller devices may be singulated from the array of memory controller devices at act 624, such as by sawing, scoring and separating, and combinations thereof.

An array of memory devices may be formed at act 630, such as by semiconductor device processing at the wafer level. Such memory devices may include 3D NAND memory devices or DRAM memory devices. Individual memory devices may be singulated from the array of memory devices at act 632, such as by sawing, scoring and separating, and combinations thereof. Two memory devices may be stacked and interconnected with originating wire-bonds at act 634. At least two memory die groups are assembled on a carrier substrate at act 636, such as the assembly of the L1 assembly 112 and the L2 assembly 120 at the carrier substrate 110 illustrated in FIG. 1A and FIG. 1C, as well as wire-bonding intervening and originating wire-bond interconnects such as the L1 first-die intervening wire-bond interconnect 140 and the originating wire-bond interconnect 158 at FIG. 1D.

Assembly of at least two memory die groups to an interposer device and to a memory controller device is done at act 640. Such assembly may include reflowing an electrical interconnect array such as the electrical connections 128 (FIG. 1), and wire-bonding to the interposer device.

Assembly of at least two memory die groups with the memory controller device and the redistribution device to a package board may be done at act 650, such as by reflow of electrical connections including a land-side electrical contact array 132 (FIG. 1F). In some embodiments, the package board, such as the package board 130, may also be initially in a wafer level array; and individual package boards may be singulated from an array at act 652, such as by such as by sawing, scoring and cracking, and combinations thereof.

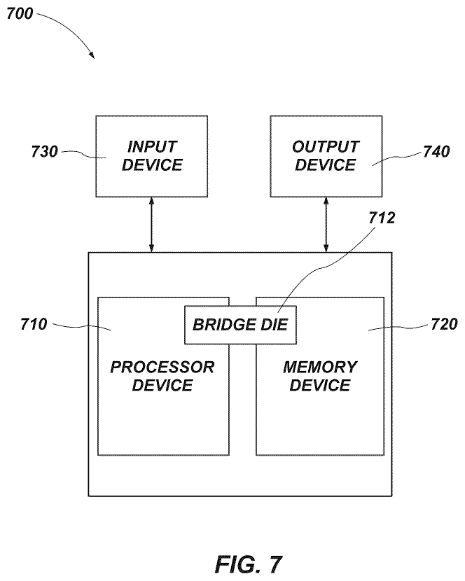

Assembly of at least one fan-in wire-bonded memory device package may be done at act 660, to be assembled to an electronic system, such as the electronic system 700 illustrated in FIG. 7.

Thus, in accordance with embodiments of the disclosure, a microelectronic device includes a controller device, a first die vertically overlying the controller device, a second die vertically overlying the first die, and a wire. The first die includes a first pad horizontally separated from a horizontal center of the controller device by a first distance. The second die includes a second pad horizontally separated from the horizontal center of the controller device by a second distance larger than the first distance. The wire contacts the first pad of the first die and the second pad of the second die.

Furthermore, in accordance with embodiments of the disclosure, a memory device package includes a memory controller device vertically overlying a package board, a first die vertically overlying the memory controller device and including a first bond pad, a second die vertically overlying the first die and including a second bond pad, and a first wire bonded to the first bond pad of the first die and the second bond pad of the second die. A horizontal center of the memory controller device is horizontally spaced farther away from the second bond pad of the second die than the first bond pad of the first die.

Microelectronic devices (e.g., the flip-chip, fan-in memory device assembly 100, the iRDL flip-chip, fan-in memory device assembly 200, the wire-bonded memory device controller fan-in microelectronic device assembly 300, and the X-Y symmetrical microelectronic device 400) of the disclosure may be used in embodiments of electronic systems of the disclosure. For example, FIG. 7 is a block diagram of an electronic system 700, according to embodiments of disclosure. The electronic system 700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, or a navigation device, etc. The electronic system 700 includes at least one memory device 720 such as any of the microelectronic device assemblies 100, 200, 300 or 400. The memory device 720 may include, for example, one or more of the microelectronic devices (e.g., the flip-chip, fan-in memory device assembly 100, the iRDL flip-chip, fan-in memory device assembly 200, the wire-bonded memory device controller fan-in microelectronic device assembly 300, or the X-Y symmetry flip-chip, fan-in memory device assembly 400) of the disclosure. The electronic system 700 may further include at least one electronic signal processor device 710 (often referred to as a “microprocessor”) that is part of an integrated circuit. While the memory device 720 and the electronic signal processor device 710 are depicted as two (2) separate devices in FIG. 7, in additional embodiments, a single (e.g., only one) memory/processor device having the functionalities of the memory device 720 and the electronic signal processor device 710 is included in the electronic system 700. In such embodiments, the memory/processor device may include, for example, one or more of the microelectronic devices (e.g., the flip-chip, fan-in memory device assembly 100, the iRDL flip-chip, fan-in memory device assembly 200, the wire-bonded memory device controller fan-in microelectronic device assembly 300, or the X-Y symmetry flip-chip, fan-in memory device assembly 400) of the disclosure. The electronic signal processor device 710 and the memory device 720 may be part of a disaggregated-die assembly 710 and 720. The disaggregated-die assembly 710 and 720 may be coupled among the electronic signal processor device 710 and the memory device 720 by a multi-die silicon bridge 712 (bridge die 712).

The electronic system 700 may further include one or more input devices 730 for inputting information into the electronic system 700 by a user, such as, for example, a mouse or other pointing device, a keyboard, a touchpad, a button, or a control panel. The electronic system 700 may further include one or more output devices 740 for outputting information (e.g., visual or audio output) to a user such as, for example, a monitor, a display, a printer, an audio output jack, and/or a speaker. In some embodiments, the input device 730 and the output device 740 may comprise a single touchscreen device that can be used both to input information to the electronic system 700 and to output visual information to a user. The input device 730 and the output device 740 may communicate electrically with one or more of the memory device 720 and the electronic signal processor device 710.

Thus, in accordance with embodiments of the disclosure, an electronic system includes an input device, an output device, a processor device operably coupled to the input device and the output device, and a memory device operably coupled to the processor device. The memory device includes a controller device, a first die, a second die, and a wire. The first die vertically overlies and horizontally overlaps the controller device, and includes a first bond pad. The second die vertically overlies and horizontally overlaps the first die, and includes a second bond pad. A horizontal center of the controller device is positioned horizontally closer to the first bond pad of the first die than the second bond pad of the second die. The wire is bonded to the first bond pad of the first die and the second bond pad of the second die.

The disclosure advantageously facilitates one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a controller device;
a first die vertically overlying the controller device and comprising a first pad horizontally separated from a horizontal center of the controller device by a first distance;
a second die vertically overlying the first die and comprising a second pad horizontally separated from the horizontal center of the controller device by a second distance larger than the first distance; and
a wire contacting the first pad of the first die and the second pad of the second die.

2. The microelectronic device of claim 1, further comprising an interposer device vertically underlying and coupled to the controller device.

3. The microelectronic device of claim 2, further comprising an additional wire contacting the first pad of the first die and a third pad of the interposer device.

4. The microelectronic device of claim 2, further comprising conductive structures vertically interposed between and coupling interposer device and the controller device, the conductive structures comprising one or more of solder bumps, electrical pillars, electrical bumps, and interconnect pins.

5. The microelectronic device of claim 1, wherein the controller device comprises an integrated redistribution layer (iRDL) at lower end thereof.

6. The microelectronic device of claim 5, further comprising an additional wire contacting the first pad of the first die and a third pad of the iRDL.

7. The microelectronic device of claim 1, wherein:
the first pad is located at a lower surface of the first die; and
the second pad is located at a lower surface of the second die.

8. The microelectronic device of claim 1, further comprising:
a third die vertically overlying the second die and comprising a third pad horizontally separated from the horizontal center of the controller device by a third distance;
a fourth die vertically overlying the third die and comprising a fourth pad horizontally separated from the horizontal center of the controller device by a second distance larger than the first distance; and
an additional wire contacting the third pad of the third die and the fourth pad of the fourth die.

9. The microelectronic device of claim 8, wherein the third pad of the third die and the fourth pad of the fourth die are each completely horizontally offset from the first pad of the first die and the second pad of the second die.

10. The microelectronic device of claim 8, wherein major portions of the first die and the second die are horizontally interposed between the wire and the additional wire.

11. The microelectronic device of claim 8, further comprising:
a redistribution device vertically underlying the controller device and comprising a fifth pad and a sixth pad, the fifth pad positioned proximate a different horizontal end of the redistribution device than the sixth pad;
a further wire contacting the first pad of the first die and the fifth pad of the redistribution device; and
an other wire contacting the third pad of the third die and the sixth pad of the redistribution device.

12. A memory device package, comprising:
a memory controller device vertically overlying a package board;
a first die vertically overlying the memory controller device and comprising a first bond pad;
a second die vertically overlying the first die and comprising a second bond pad, a horizontal center of the memory controller device horizontally spaced farther away from the second bond pad of the second die than the first bond pad of the first die; and
a first wire bonded to the first bond pad of the first die and the second bond pad of the second die.

13. The memory device package of claim 12, wherein the memory controller device, the first die, and the second die all horizontally overlap one another.

14. The memory device package of claim 12, further comprising an interposer device coupled to the package board and vertically interposed between the package board and the memory controller device, the interposer device horizontally overlapping the memory controller device.

15. The memory device package of claim 14, further comprising conductive structures vertically interposed between and coupled to interposer device and the memory controller device.

16. The memory device package of claim 14, further comprising a second wire bonded to the first bond pad of the first die and an additional bond pad of the interposer device.

17. The memory device package of claim 12, wherein the memory controller device comprises:
control logic circuitry; and
an integrated redistribution layer (iRDL) vertically interposed between the control logic circuitry and the package board.

18. The memory device package of claim 17, further comprising a second wire bonded to the first bond pad of the first die and an additional bond pad of the iRDL.

19. The memory device package of claim 12, wherein the first die and the second die each include an array of NAND memory cells.

20. An electronic system, comprising:
an input device;
an output device;
a processor device operably coupled to the input device and the output device; and
a memory device operably coupled to the processor device, the memory device comprising:
a controller device;
a first die vertically overlying and horizontally overlapping the controller device, the first die comprising a first bond pad;
a second die vertically overlying and horizontally overlapping the first die and comprising a second bond pad, a horizontal center of the controller device positioned horizontally closer to the first bond pad of the first die than the second bond pad of the second die; and
a wire bonded to the first bond pad of the first die and the second bond pad of the second die.
